(19) United States
(12) Patent Application Publication
(10) Pub. No.: US 2010/0109783 A1
(43) Pub. Date: May 6, 2010

(54) Reconfigurable Amplifier and Filter Using Time-Varying Circuits

(75) Inventor: Jose L. Bohorquez, Cambridge, MA (US)

Correspondence Address: HOUSTON ELISEEVA, 4 MILITIA DRIVE, SUITE 4, LEXINGTON, MA, 02421, US

(73) Assignee: T-VAR SEMICONDUCTOR, LLC, Cambridge, MA (US)

(21) Appl. No.: 12/263,626

(22) Filed: Nov. 3, 2008

(51) Int. Cl. H03H 11/12; H03F 3/68; H03G 3/30

(52) U.S. Cl. 330/302; 330/295; 330/278

(57) ABSTRACT

A reconfigurable system is used for amplifying, filtering, and sampling analog signals. Unlike conventional analog filters and amplifiers based on linear time-invariant systems and classical filter responses such as Butterworth or Chebyshev filters, the system described here uses parallel branches comprising time-varying circuits. An input voltage or current is communicated to a number of parallel branches and each branch processes a segment of the input signal using time-varying circuits such as analog multipliers and/or super-regenerative amplifiers. The time-window of the input signal processed by each branch is equal in length, but offset in time from all other branches. The output of each branch is a series of filtered and amplified samples of the input signal. The output samples of all branches are then time-interleaved in the analog domain, or digitized using separate analog-to-digital converters and then time-interleaved digitally. By using time-varying circuits, sharper filters and greater amplification is achieved while consuming less integrated-circuit area and power. The time-varying circuits in each branch are controlled by synthesized signals that determine the filter response and gain of the overall system. As a result, better flexibility and reconfigurability are achieved compared with classical filters and amplifiers.

### BACKGROUND OF THE INVENTION

Analog and mixed-signal amplifiers and filters (hereafter A&F) are used extensively in electronics to reduce the impact of noise and unwanted signals. Most analog A&F use capacitors, resistors, and/or inductors along with circuits such as operational amplifiers (hereafter op-amps) to achieve transfer functions with poles and zeros. The frequency response of such an A&F is determined by the position of the transfer function's poles and zeros in the complex plane. The pole locations in such A&F are static, making the systems linear and time-invariant (LTI). There are many ways to implement these A&F including, but not limited to: (1) fully passive implementations only using resistors, capacitors and inductors, (2) active resistance-capacitance (active-RC) implementations that use op-amps, and (3) transconductance-capacitance (Gm-C) implementations.

There are many tradeoffs between these different implementations including signal corruption by noise, signal degradation due to nonlinearity, system power consumption, and area consumption for integrated circuit (hereafter IC) designs.

Fully passive implementations are often inadequate in IC designs because they cannot implement complex poles without the use of inductors. To achieve low-frequency poles, the necessary inductors sizes are impractical limiting filter transfer functions to real poles that cannot achieve high levels of performance.

Active-RC implementations are far more suitable and popular for implementing analog A&F systems in IC designs, but require high gain op-amps for proper operation. Modern scaled CMOS processes pose many challenges in designing high-gain op-amps due to the reduced intrinsic gain of transistors, reduced supply voltages, and increased threshold voltage variations. Gm-C filters face similar challenges since the output resistance of the transconductors must be very high. This requirement is difficult to achieve in scaled CMOS because the intrinsic output resistance of transistors is reduced and cascoding is challenging due to the low supply voltages. These challenges point to the need for analog A&F that do not require high gain op-amps or high output resistance transconductors.

Another drawback of analog A&F systems is that they often consume large amounts of area compared with digital circuits. The cost ICs is proportional to their size, so minimizing their area is critical. The area of analog filters is often dependent on the noise requirements of the system along with the frequency response requirements. To achieve low noise design, it is generally necessary to use larger capacitors which consume large amounts of area. To achieve sharp filtering, it is typically necessary to use multiple, cascaded filtering stages increasing power and area consumption.

To maximize the performance of cascaded analog A&F systems, the gain of each stage should be variable. This is often done using op-amps along with variable resistors or transconductors. To achieve good linearity, it is often necessary to use resistors that allow for discrete values of achievable gain. It is therefore challenging to achieve good resolution in the achievable variable gain. As with the filtering functionality of classical A&F systems, the use of op-amps for amplification leads to higher power consumption and significant challenges in scaled CMOS.

Mixed signal or discrete-time A&F systems are alternatives to analog A&F systems. In discrete-time filters, an analog signal is first sampled at a rate that is typically at least twice as high as the bandwidth of the input signal. Discrete-time transfer functions with static poles and zeros are then used to filter and amplify the sampled signal. A common implementation of mixed-signal filters is the switch-capacitor filter. A challenge that arises with discrete-time filters, however, is that undesired signals at high frequencies require high sampling rates. If sufficiently high sampling rates are not used, aliasing occurs, degrading the desired signal. Using high sampling rates, however, can be challenging and power hungry. Furthermore, most implementations of discrete-time analog filters use large capacitors that consume relatively large amounts of area.

Digital filters, such as finite impulse response (FIR) filters, are used to filter signals that have already been digitized using an analog-to-digital converter (ADC). As in discrete-time filters, the original analog signal must be sampled at a high enough rate to avoid aliasing. This often requires that an additional anti-aliasing filter be used before the ADC. Furthermore, if undesired signals are much larger than the desired signal, stringent requirements are placed on the dynamic range of the ADC. This often requires the use of large sampling capacitors to reduce kT/C noise along with fast, high gain op-amps that consume large amounts of power.

Each of the three types of A&F systems described above (analog, discrete-time, and digital), have benefits and drawbacks and all have found wide popularity in modern electronic designs. As CMOS continues to scale, however, serious challenges arise in the design of the high gain op-amps and high output resistance transconductors used for such systems. Furthermore, these classical A&F topologies require large areas and high power consumption to achieve low noise filtering with sharp frequency responses. Consuming a large area is undesirable because it increases the cost of the system. Consuming large amounts of power is undesirable for portable devices because it results in shorter battery life.

A fourth type of A&F that is far less popular but holds great promise is the super-regenerative amplifier. While radio-frequency (RF) SRAs have enjoyed some popularity in low-power receivers, baseband SRAs (hereafter simply SRAs) have not. The concept of super-regenerative amplification was first introduced by Edwin Armstrong in 1922. Since then, RF SRAs have enjoyed some popularity in low-power receivers due to their relative architectural simplicity. In its simplest form, an RF SRA has a single active element (such as a transistor) and a parallel resistor-inductor-capacitor (RLC) network. The active element is used to provide time-varying positive feedback that periodically changes the location of the two poles of the RLC network so that the system alternates between stability and instability. The details of how that positive feedback is varied determine the filtering and amplifying qualities of the RF SRA.

SRAs are similar to RF SRAs except they do not use an inductor. As a result, their resistor-capacitor (RC) network only has one pole whose location is varied as a function of time. The periodic signal that controls the positive feedback in SRAs is often referred to as the quench signal, and the rate at which it repeats itself is referred to as the quench frequency. SRAs are inherently sampling systems with a sampling frequency equal to the quench frequency. The input signal to an SRA is an analog signal and the output, which is taken at the end of the quench cycle, is a discrete-time signal.

The sampling nature of SRAs presents a challenge when they are used as filters. To avoid aliasing, the quench frequency in an SRA must be at least as high as the Nyquist rate defined as two times the highest significant spectral component of the input signal. Assuming that no anti-aliasing filter is used, the filtering achieved by the SRA must be sufficient to attenuate unwanted components of the input signal that would cause aliasing. This condition poses challenges to SRA designs because of a tradeoff that exists between the bandwidth of the SRA filter and the sampling rate required to avoid aliasing. It can be shown that the bandwidth of an SRA is proportional to the quench frequency. As a result, increasing the quench frequency leads to a higher SRA bandwidth and precludes the SRA from serving as its own anti-aliasing filter.

A second challenge that limits the performance of SRAs has to do with its impulse response. It can be shown that the discrete-time impulse response of an SRA's transfer function is an exponential. The exponent of the impulse response is a function of the quench signal. This exponential relationship restricts the impulse response to purely non-negative values and therefore limits the frequency response of the SRA. Despite this limitation, SRAs have exceptional filtering qualities considering they use only one pole. Classical LTI filters with a single pole have magnitude-versus-frequency relationships that roll off at a rate of 20 dB per decade. Due to the time-varying nature of SRAs they can achieve much sharper roll-off.

Despite the drawbacks of SRAs described above, there are various benefits that hold great promise. First, very large amounts of gain can be achieved using poor quality active devices because of the positive feedback and time-varying nature of SRAs. This could help alleviate the aforementioned challenges of scaled CMOS that lead to low-gain op-amps and low output resistance transconductors. In contrast to active circuits in classical filters that require high gain devices, the active devices in SRAs need only provide a gain slightly larger than one.

A second benefit of using SRAs is that relatively sharp filtering can be achieved with a single pole. This has the benefit of reducing area consumption and power. A third benefit is that the bandwidth of the filter is not strictly defined by the values of the resistance and capacitance of the SRA. Instead, the characteristics of the quench signal serve as a third variable that affects the frequency response of the filter. This has the potential to reduce the overall area of the filter since smaller capacitors can be used to achieve the same bandwidth as classical LTI filters while still achieving low-noise design. Furthermore, the bandwidth, frequency response, and gain can be tuned by modifying the quench signal instead of the resistance or capacitance.

To summarize, filtering and amplification are necessary in most electronic systems. Modern electronic systems use op-amps or transconductors along with resistors and capacitors to provide variable gain, but typically cannot provide fine resolution steps. Filtering in modern electronic systems is done with analog, discrete-time, or digital filters that also use op-amps and transconductors. Scaled CMOS technologies present challenges to designing systems that require the use of high gain op-amps or high output resistance transconductors. Furthermore, classical filter topologies require large areas and high power consumption to achieve low noise filters with sharp frequency responses. Consuming a large area is undesirable because it increases the cost of the system. Consuming large amounts of power is undesirable for portable devices because it results in shorter battery life.

### SUMMARY OF THE INVENTION

Systems using SRAs have the potential to achieve better performance than classical A&F systems while consuming less power and area. However, there are drawbacks to SRAs that must be overcome to maximally exploit their potential.

It is, therefore, a general object of the current invention to provide variable-gain amplification and sharp, reconfigurable filtering to analog signals while consuming less area and power than modern amplifier and filter systems. A supporting object of the invention is to resolve issues associated with SRAs to make effective use of them in A&F systems.

The present invention relates generally to analog and mixed-signal electrical filters and amplifiers and, more particularly, to filters and amplifiers integrated and manufactured according to scaled semiconductor processes.

In the present invention, an electrical system uses N parallel branches comprising time-variable circuits to concurrently filter, amplify, and sample an analog input signal. An input voltage or current is communicated to N parallel branches and each branch processes a segment of the input signal using time-varying circuits such as analog multipliers and/or super-regenerative amplifiers. Each branch periodically processes a time-window of the input signal and yields a filtered and amplified sample of that segment. The time-window of the input signal processed by each branch is equal in length, but offset in time from all other branches. More specifically, if the time-windows are T_{q} seconds in length and there are N parallel branches, then the time window of one branch is offset by Tₛ=T_{q}/N seconds compared to the time window of an adjacent branch. The output samples of all branches can be time-interleaved in the analog domain, and then digitized using a single analog-to-digital converter (ADC), or digitized using separate ADCs and then time-interleaved digitally.

By using time-varying circuits, sharper filters and greater amplification is achieved while consuming less IC area and power. IC area is reduced because the bandwidth of the filter is not strictly determined by the size of the resistors and capacitors. Instead, the control signals that communicate with the time-varying circuits in each branch of the system provide additional variables that set the filter bandwidth. As a result, smaller capacitors and resistors can be used. Furthermore, a single time varying circuit can achieve much sharper filtering than a single filtering stage in a classical LTI filter. To achieve comparable filtering performance, LTI filters require a cascade of various stages resulting in larger area and power consumption.

Power consumption in classical LTI filters is largely due to the high-gain op-amps or high output resistance transconductors required. In contrast, time-varying circuits such as analog multipliers and SRAs require minimal gain. In the case of SRAs, required gain is slightly greater than one. This means that each branch of the proposed A&F system consumes considerably less power than an op-amp, and even when N branches are used, the overall system power consumption is reduced.

Better flexibility and reconfigurability are also achieved in the present invention compared with classical filters and amplifiers. This is because the time-varying circuits in each branch of the system are controlled by synthesized signals that determine the filter response and gain of the overall system. As a result, filtering qualities of the system can be reconfigured by changing the rates at which the system is clocked and the shape of the signals controlling the time-varying circuits.

The sample rate of the system described (fₛ) is chosen to be at least twice the bandwidth of the filter response of the system to prevent aliasing. The corresponding time between samples is Tₛ=1/fₛ.

Two time-varying circuits that can be used separately or in conjunction are analog multipliers and SRAs. As explained previously, there are two fundamental challenges that limit the filtering performance of SRAs. The first challenge is associated with the relationship between the quench frequency of SRAs and their filter bandwidth. More specifically, it is generally difficult to set an SRA's filter bandwidth low enough while still sampling fast enough to avoid aliasing. The second challenge associated with SRAs is that their impulse response is restricted to non-negative values as a result of its exponential nature.

The first challenge associated with SRAs is overcome by using N parallel branches, each with one SRA. That is to say, in contrast with typical systems using a single SRA, by using N parallel SRAs the strict relationship between sampling rate and SRA bandwidth is broken. This is because the sampling rate is not longer equal to the quench frequency, but rather fₛ=N×f_{q}, where f_{q} is the quench frequency. By using a high enough number of parallel branches (each with an SRA), the sampling rate can be made high enough to avoid aliasing while using the SRA as its own anti-aliasing filter.

The second challenge associated with SRAs is the strictly non-negative filter impulse response. In the present invention, this challenge is overcome by preceding each SRA with an analog multiplier. In the most general implementation of the invention, the multiplicand input of the analog multiplier communicates with the input signal and the multiplier input of the multiplier communicates with a multiplier signal synthesized by a digital-to-analog converter (DAC). The output of each analog multiplier communicates with the signal input of the SRA and a quench signal generator communicates with the control input of the SRA in each block. The resulting impulse response of the overall filter is the product of the multiplier signal connected to the analog multiplier and the inherent impulse response of the SRA. Since the multiplier signal can take on positive or negative values, the overall filter impulse response is no longer restricted to non-negative values. A result of the added flexibility afforded by the multipliers is that sharper filters can be created compared with embodiments of the invention without multipliers.

The amount of gain provided by each SRA is strongly dependent on the characteristics of the quench signal. As explained previously, the quench signal controlling each SRA periodically alternates the SRA between stable and unstable states. If the quench signal allows the SRA to remain in the unstable region for a longer period of time, higher gain is achieved. As a consequence, the gain of the SRA can be controlled using variable clocks. Clock signals in modern CMOS technologies can be very accurate, and therefore, the exact amount of gain provided by the SRA can be controlled with excellent precision.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a block diagram of an embodiment of the invention comprising N parallel branches.

FIG. 2 is a block diagram of another embodiment of the invention.

FIG. 3 is a block diagram of yet another embodiment of the invention.

FIG. 4 is a block diagram of an embodiment of one of the amplify-and-filter blocks used in the invention comprising an analog multiplier and a super-regenerative amplifier.

FIG. 5 is a block diagram of another embodiment of one of the amplify-and-filter blocks used in the invention comprising an analog multiplier.

FIG. 6 is a block diagram of yet another embodiment of one of the amplify-and-filter blocks used in the invention comprising a super-regenerative amplifier.

FIG. 7 is a circuit diagram of a general implementation of a super-regenerative amplifier.

FIG. 8 is a timing diagram illustrating the input signal along with examples of control signals used in two branches and their respective output signals.

### DETAILED DESCRIPTION OF THE PREFERRED EMBODIMENTS

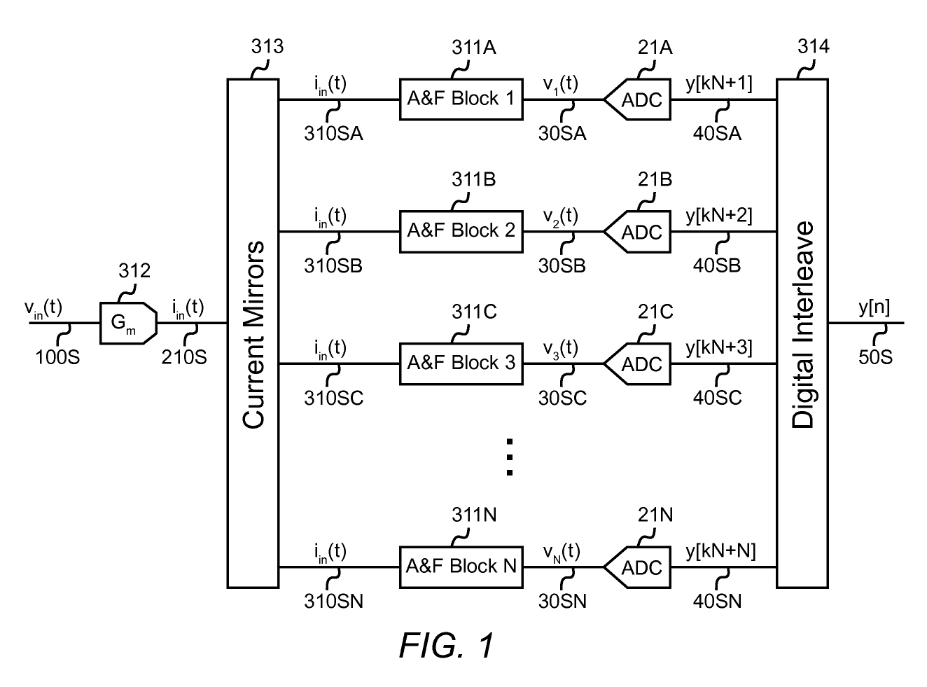

FIG. 1 shows an embodiment of the invention with analog input voltage signal 100S which is a continuous function of time vᵢₙ(t). Signal 100S communicates with a transconductor 312 whose output is an analog current 210S which is a continuous function of time iᵢₙ(t). The current mirror 313 replicates current 210S and has as its outputs identical current signals 310SA-310SN (generally 310S) where 310SN represents the current in the N^{th} branch of the system. Each branch has one of N A&F blocks 311A-311N (generally 311) whose output signal 30SA-30SN (generally 30S) is a voltage vₙ(t), where n is a number between 1 and N corresponding to the particular branch.

The output 30S of each A&F block 311 communicates with one of N ADCs 21A-21N (generally 21). Each ADC has the same sampling rate of f_{q}=fₛ/N. However, the sampling instant of each ADC is different. More specifically, the sampling instant of the n^{th} ADC is offset in time from the sampling instant of the (n+1)^{th} ADC by Tₛ=1/fₛ seconds. The output of all ADCs (21A-21N) are interleaved with digital block 314 whose output 50S is the digital signal labeled y[n]. Signal 50S is a filtered, amplified, and digitized version of signal 100S.

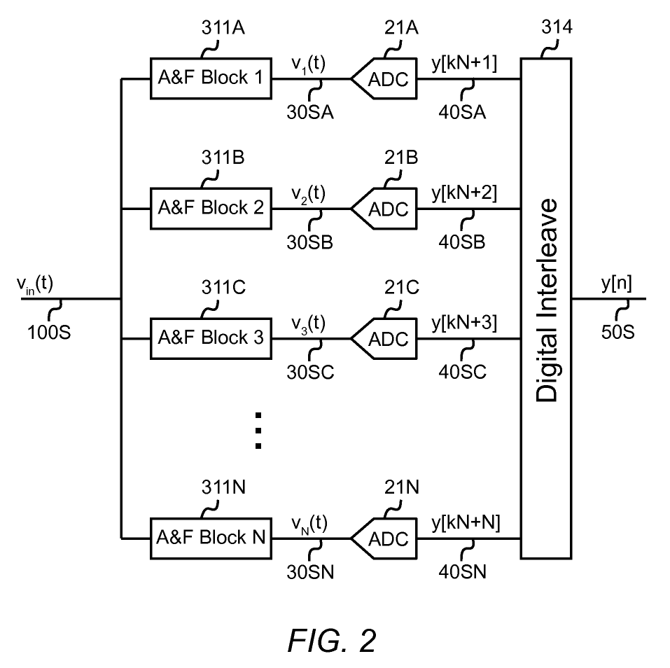

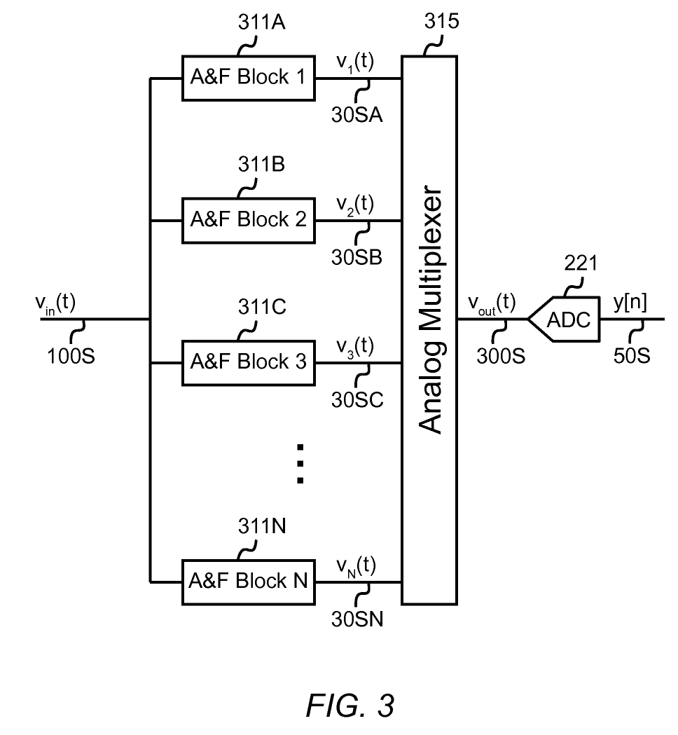

FIG. 2 shows another embodiment of the invention where an input voltage signal 100S is directly communicated to all A&F blocks 311. The overall functionality of the system is similar except for minor details in the implementation of 311. FIG. 3 shows yet another embodiment of the invention in which a single ADC 221 is used to digitize the output of all A&F blocks 311. In this embodiment, an analog multiplexer 315 is used to periodically connect the output of each A&F block 311 to the input of ADC 221. ADC 221 then digitizes signals 30A-30N at a sampling rate fₛ. The benefit of this embodiment is that a single ADC is used. One drawback of this embodiment is that ADC 221 must operate at a much faster rate than ADCs 21 in the embodiments of FIGS. 1 and 2. A second drawback is that this embodiment leads to more complicated analog routing which is typically more difficult to employ than digital routing.

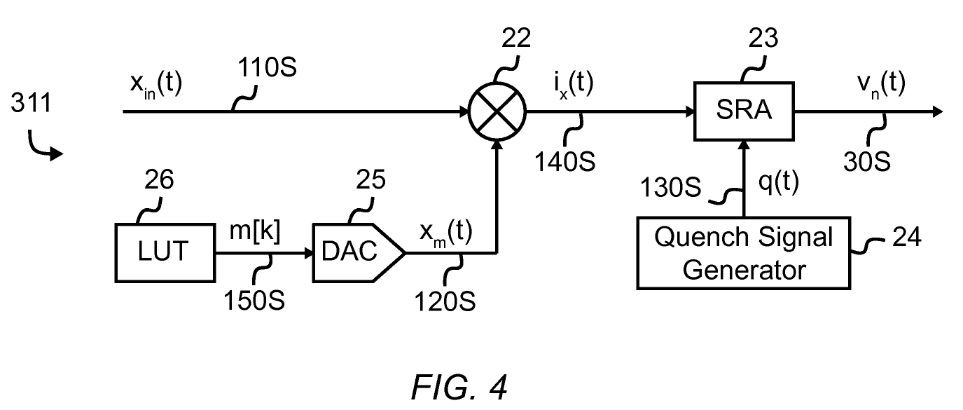

FIG. 4 shows one embodiment of one of the A&F blocks 311 in FIG. 1. For the embodiment of the invention in FIG. 1 where the input to 311 is a current 10S, the signal 110S labeled Xᵢₙ(t) in FIG. 4 is equivalent to one of the signals 310S labeled iᵢₙ(t) in FIG. 1. The signal 110S communicates with the multiplicand input of the analog multiplier 22. A signal 120S, labeled xₘ(t), is a synthesized analog signal that can be a voltage or a current depending on the topologies of 22 and 25. Signal 120S is synthesized by a DAC 25 whose input is the digital signal 150S labeled m[k]. The signal 150S can be generated by clocking through a look-up-table (LUT) 26 at some bit rate higher than fₛ/N. Signals 150S and 120S are both periodic with period T_{q}=N×Tₛ.

The output of analog multiplier 22 in FIG. 4 is a current 140S labeled iₓ(t) that is communicated to the signal input terminal of SRA 23. The control input terminal of 23 communicates with a signal 130S labeled q(t) that is generated by the quench signal generator 24. Signal 130S is also periodic with period T_{q}=N×Tₛ. More specifically, the repetition of signals 120S and 130S constitute a quench cycle with quench frequency f_{q}=fₛ/N, or equivalently, quench period T_{q}=N×Tₛ. The SRA's output signal 30S labeled vₙ(t) is a continuous time analog voltage, but its output is only valid at the end of each quench cycle.

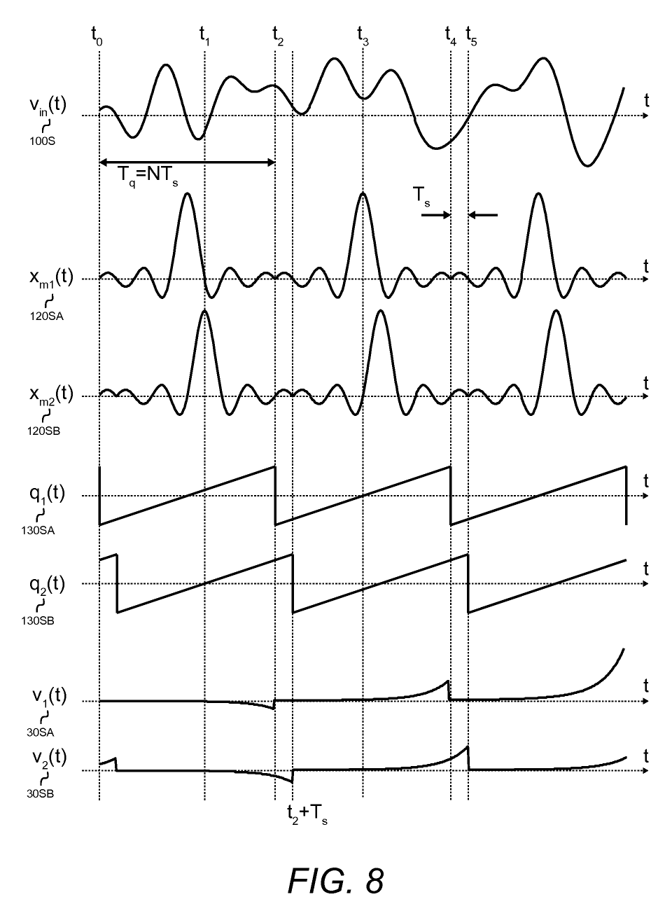

FIG. 8 helps explain the relationship between different signals in each A&F block 311 and between the blocks 311A-311N. The respective signals 120S and 130S in each A&F block 311 in FIG. 1 all have the same period, but are offset by time Tₛ with respect to the block 311 in their adjacent branches. FIG. 8 shows an example where signals 120SA and 130SA correspond to A&F block 311A, and signals 120SB and 130SB correspond to the A&F block 311B. As shown in FIG. 8, signals 120SA and 120SB are identical except for a time delay Tₛ. The same is true for signals 130SA and 130SB. The output signals 30SA and 30SB of 311A and 311B are not merely offsets of each other because they depend on the input signals 310SA and 310SB which are not periodic. As explained previously, signals 310SA-310SN are identical currents and scaled versions input signal 100S.

Signal 30SA in FIGS. 1 and 8 is sampled and digitized by ADC 21A at the end of each quench cycle which occurs every T_{q} seconds (for example, at times t₀, t₂, and t₄). Similarly, signal 30SB is sampled and digitized by ADC 21B every T_{q} seconds, but offset from the samples of 21A by Tₛ seconds (for example, at times t₀+Tₛ, t₂+Tₛ, and t₄+Tₛ). Generally, ADC 21n samples and digitizes signal 30Sn at times t₀+n×Tₛ, t₂+n×Tₛ, t₄+n×Tₛ, etc. The result is that there is a distinct sample of a filtered and amplified version of the input signal 100S every Tₛ seconds. Equivalently, the input signal 100S is filtered, amplified, and sampled at a rate fₛ.

For slow-varying input signals 100S, FIG. 8 also shows that the output signals 30SA and 30SB are proportional to the amplitude of signal 100S near the instants when the respective signals 130SA and 130SB cross the time axis (i.e. have values of zero). To illustrate this, note that at time t₁ in FIG. 8, signal 130SB crosses the time axis and signal 100S has a small negative value. As a result, at time t₂+Tₛ, signal 30SB has a small negative value. In contrast, at time t₃, signal 130SA crosses the time axis and signal 100S has a positive value that is larger in magnitude than at time t₁. As a result, at time t₄, signal 30SA is positive and has a value that is larger in magnitude than 30SB at time t₂+Tₛ. Generally, for the n^{th} branch, at the end of a quench cycle (when 30Sn is digitized), the value of signal 30Sn is proportional to the value of 100S at the instant 130Sn crossed the time axis during that quench cycle.

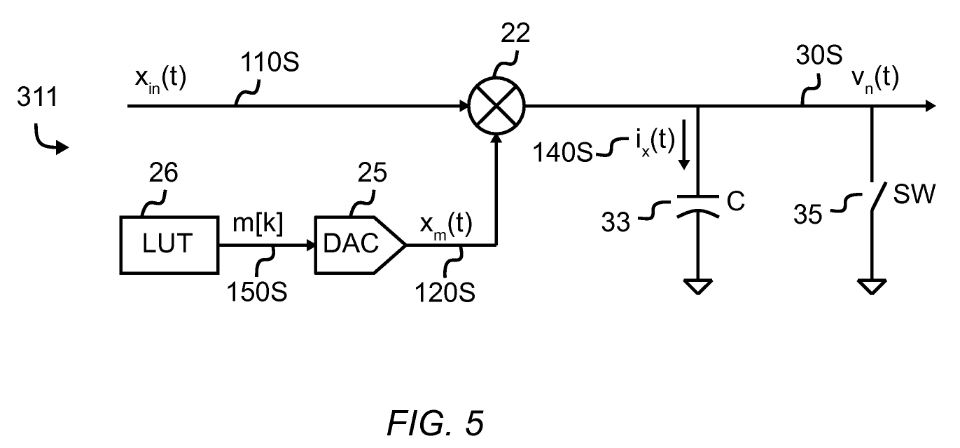

The embodiment of A&F block 311 shown in FIG. 4 is particularly advantageous because it enhances the filtering and amplifying benefits of an SRA with the flexibility in frequency response afforded by using an analog multiplier. FIG. 5 shows an alternative, though less advantageous, embodiment of the A&F block 311 in which only an analog multiplier 22 and its supporting circuitry are used. The output of 22 in this embodiment is current 140S labeled iₓ(t) in FIG. 5. Current 140S is time-integrated onto capacitor 33 during each quench cycle resulting in a filtered version of signal 110S. The filtering qualities of this embodiment are strongly dependent on signal 120S. At the end of each quench cycle, switch 35 is used to reset voltage signal 30S back to zero.

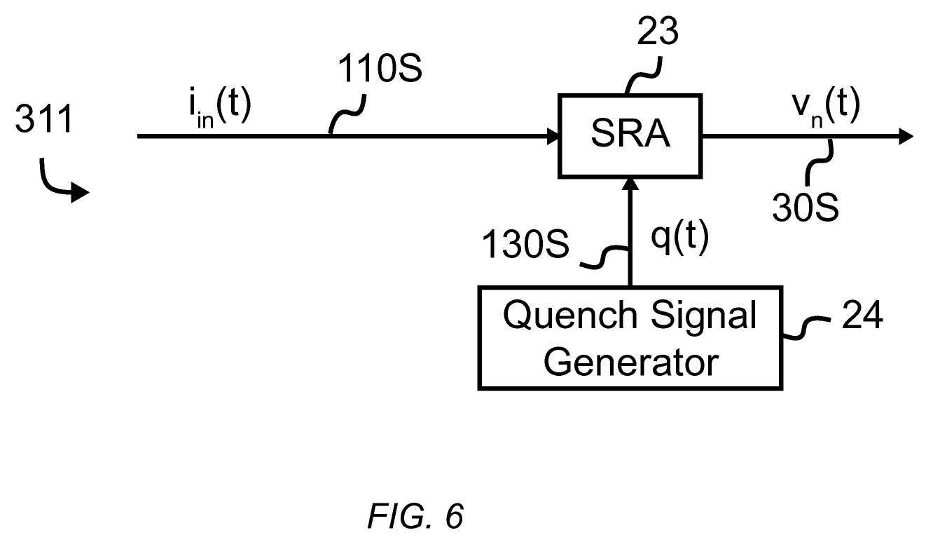

FIG. 6 shows yet another embodiment of A&F block 311 in which SRA 23 and its supporting circuitry are used without an analog multiplier preceding it. The drawback to this approach is that the impulse response of the effective filter transfer function is restricted to non-negative values. This restricts the filtering qualities of the overall system and results in a less desirable frequency response compared to the embodiment in FIG. 4.

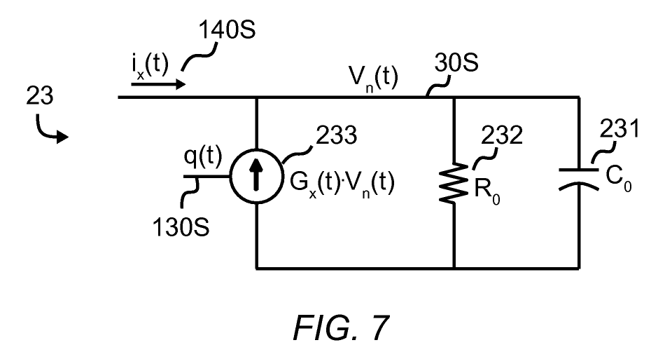

FIG. 7 shows a general circuit implementation of SRA 23. SRA 23 includes a capacitor 231, a resistor 232, and a signal-controlled transconductor 233. The transconductance of 233 (labeled Gₓ(t)) is a function of signal 130S. The output current of 233 is proportional to signal 30S resulting in positive feedback. One of many possible relationships between Gₓ(t), R₀, and q(t) is:

$$\begin{matrix}{G}_{x} ( t ) = \frac{1}{{R}_{0}} ( 1 + q ( t ) ) \\ = {G}_{0} ( 1 + q ( t ) ) .\end{matrix}$$

The filtering and amplifying qualities of SRA 23 can be explained using the solution to the time-varying differential equation describing the circuit in FIG. 7:

vₙ(t)G₀+\dot{v}ₙ(t)C₀=iₓ(t)+Gₓ(t)vₙ(t).

Making a substitution for Gₓ(t), this differential equation can be rewritten as

$${\dot{v}}_{n} ( t ) - q ( t ) {v}_{n} ( t ) ( \frac{{G}_{0}}{{C}_{0}} ) = \frac{{i}_{x} ( t )}{{C}_{0}} .$$

Since we are only interested in the value of vₙ(t) at the end of each quench cycle, and the cycle is repeated periodically, solving a single quench cycle is sufficient to find the response of the SRA to an input current. Solving the differential equation above over a single quench cycle (for example, from time t=0 to t=T_{q}) yields the solution

$${v}_{n} ( {T}_{q} ) = \frac{1}{{C}_{0}} {e}^{\frac{{G}_{0}}{{C}_{0}} {\int }_{0}^{{T}_{q}} q ( τ ) d τ} \times {\int }_{0}^{{T}_{q}} {e}^{- \frac{{G}_{0}}{{C}_{0}} {\int }_{0}^{λ} q ( τ ) d τ} {i}_{x} ( λ ) d λ .$$

The first exponential term in this solution describes the time-dependent gain of the SRA. For particular values of C₀, R₀, and q(t), longer quench cycles yield higher gain. The integral in the above solution is responsible for the filtering provided by the SRA. To understand this better, a term called the sensitivity function of the SRA can be defined as

$$s ( t ) = \{ \begin{matrix}{e}^{- \frac{{G}_{0}}{{C}_{0}} {\int }_{0}^{t} q ( τ ) d τ} & 0 < t < {T}_{q} \\ 0 & otherwise .\end{matrix}$$

Recall that the input current to the SRA is a continuous time signal. The output of the SRA, however, is a discrete-time signal since its value is sampled at times nT_{q}, where n is an integer. It can be shown that the discrete-time signal vₙ(nT_{q}) is equivalent to a filtered, amplified, and sampled version of iₓ(t). It can be further shown that the impulse response of the equivalent filter is equivalent to the sensitivity function s(t).

As explained previously, the impulse response of the filter is limited to non-negative numbers due to the exponential nature of s(t). By using multiplier 22 in FIG. 4, this limitation can be overcome. This is because iₓ(t) (140S) is the product of xᵢₙ(t) (110S) and xₘ(t) (120S). Furthermore, when using the system embodiment in FIG. 1, 120S is equivalent to vᵢₙ(t)Gₘ, so that the relationship between 100S, (vᵢₙ(t)) and 30S (vₙ(T_{q})) is

$${v}_{n} ( {T}_{q} ) = \frac{1}{{C}_{0}} {e}^{\frac{{G}_{0}}{{C}_{0}} {\int }_{0}^{{T}_{q}} q ( τ ) d τ} \times {\int }_{0}^{{T}_{q}} s ( λ ) {x}_{m} ( λ ) {i}_{x} ( λ ) d λ .$$

The result is that the impulse response of the overall filter is now

h(t)=s(t)xₘ(t).

Since xₘ(t) can take on both positive and negative values, the filter response of the equivalent filter is far more flexible.

While this invention has been particularly shown and described with references to preferred embodiments thereof, it will be understood by those skilled in the art that various changes in form and details may be made therein without departing from the scope of the invention encompassed by the appended claims.

What is claimed is:

1. A filter device having a continuous-time analog input voltage signal as its input and comprising:
i) N parallel branches that simultaneously process said input signal; and
ii) a time-varying circuit in each said branch that periodically filters and samples a segment of the input signal.

2. A filter device claimed in claim 1 that further comprises:
i) a transconductor that converts the input voltage signal into a current signal; and
ii) circuitry that replicates said current signal into N equivalent currents and communicates each current to one of the N parallel branches.

3. A filter device claimed in claim 1, wherein the input signal is a continuous-time analog input current and further comprises circuitry that replicates said current signal into N equivalent currents and communicates each current to one of the N parallel branches.

4. A filter device claimed in claim 1 wherein the time-varying circuit is a super-regenerative amplifier.

5. A filter device claimed in claim 4 that further comprises a quench-signal generator in each branch communicating to the super-regenerative amplifier in said branch.

6. A filter device claimed in claim 5 further comprising a variable clock used to vary the gain provided by each super-regenerative amplifier.

7. A filter device claimed in claim 1 wherein the time-varying circuit is an analog multiplier.

8. A filter device claimed in claim 7 that further comprises a digital-to-analog converter in each branch in communication with the analog multiplier in said branch.

9. A filter device claimed in claim 1 wherein the time-varying circuit is the series combination of an analog multiplier in communication with a super-regenerative amplifier.

10. A filter device claimed in claim 1 further comprising an analog-to-digital converter in each branch in communication with the output of the time varying circuit in said branch.

11. A filter device claimed in claim 10 further comprising circuitry to time-interleave the output of the analog-to-digital converters in each branch.

12. A filter device claimed in claim 1 further comprising an analog multiplexer to time-interleave the output of each said branch.

13. A filter device claimed in claim 12 further comprising a single analog-to-digital converter used to digitize the time-interleaved output of the analog multiplexer.

14. A filtering method comprising:
i) providing N parallel branches that simultaneously process a continuous-time analog input voltage signal; and
ii) providing a time-varying circuit in each said branch that periodically filters and samples a segment of the input signal.

15. A method claimed in claim 14 that further comprises:
i) the input voltage signal into a current signal; and
ii) replicating said current signal into N equivalent currents and communicating each current to one of the N parallel branches.

16. A method as claimed in claim 14 wherein the time-varying circuit is a super-regenerative amplifier, the method further comprises generating a quench-signal generator for each super-regenerative amplifier.

17. A method claimed in claim 14 wherein the time-varying circuit is an analog multiplier, the method comprises providing a digital-to-analog converter in each branch in communication with the analog multiplier in said branch.

18. A method claimed in claim 14 further comprising providing an analog-to-digital converter in each branch in communication with the output of the time varying circuit in said branch and the method comprises time-interleaving the output of the analog-to-digital converters in each branch.
